(19) United States
(12) Patent Application Publication
(10) Pub. No.: US 2005/0230682 A1
(43) Pub. Date: Oct. 20, 2005

(54) Thin film device, integrated circuit, electrooptic device, and electronic device

(75) Inventor: Hiroyuki Hara, Chino-shi (JP)

Correspondence Address: BANNER & WITCOFF, 1001 G STREET N W, SUITE 1100, WASHINGTON, DC, 20001, US

(73) Assignee: Seiko Epson Corporation, Shinjuku-ku (JP)

(21) Appl. No.: 11/105,477

(22) Filed: Apr. 14, 2005

(30) Foreign Application Priority Data
Apr. 16, 2004 (JP) 2004-122052(P)
Jan. 28, 2005 (JP) 2005-20988(P)

(51) Int. Cl. H01L 29/04; H01L 31/036; H01L 31/20

(52) U.S. Cl. 257/59; 257/72; 257/74; 257/66

(57) ABSTRACT

A thin film device including a plurality of thin film element layers having one or more thin film elements, wherein each of the thin film elements has one or more heat generating regions that generates heat when supplied with an electric current is provided. Each of the thin film elements is relatively placed so that the heat generating regions of the thin film elements included in one of two adjoining two thin film element layers does not overlap with the heat generating regions of the thin film elements included in the other thin film element layer in a direction of thickness of the thin film element layers.

### RELATED APPLICATIONS

This application claims priority to Japanese Application Nos. 2004-122052, filed Apr. 16, 2004 and 2005-20988, filed Jan. 28, 2005, whose contents are explicitly incorporated herein by reference.

### FIELD OF THE INVENTION

The present invention relates to a three-dimensional thin film device constructed by laminating circuit layers including thin film transistors and other thin film circuit elements.

### BACKGROUND OF THE INVENTION

The development of a three-dimensional thin film device that is constructed by laminating thin film element layers including thin film transistors and other thin film elements has been in progress. For example, a method for manufacturing a three-dimensional device by forming a transferring layer, which includes a thin film element, on a substrate, which is to become the source of transfer, and then transferring the transferring layer onto another substrate, which is to become the destination of transfer, is disclosed in Japanese Unexamined Patent Publication No. 11-251517. With such a three-dimensional device, a highly integrated device that cannot be achieved with a conventional planar (two-dimensional) layout can be obtained.

However, the above thin film device has problems. In the above thin film device constructed by laminating thin film element layers, the thickness of each thin film element layer is approximately 1 to 3 μm. That is, the distance between thin film elements included in each of adjoining layers becomes very short. Therefore, the influence of the heat, generated in each thin film element when supplied with an electric current, put on other thin film elements may hinder stable operation of the thin film device.

### SUMMARY OF THE INVENTION

Aspects of the present invention provide a thin film device that can secure stable operation by avoiding the influence of the heat generated between thin film elements placed adjoiningly in the laminated direction.

According to one aspect of the invention, a thin film device includes a plurality of laminated thin film element layers having one or a plurality of thin film elements, wherein the thin film element has a heat generating region that generates heat with a supply of an electric current and each of the thin film elements is placed so that the heat generating region of a thin film element included in one of the two adjoining thin film element layers does not overlap with the heat generating region of the thin film element included in the current thin film element layer in a direction of thickness of the thin film element layers. A thin film element as used herein means a circuit element including, but not limited to, an active element or a passive element. Examples of active elements include thin film transistors and thin film diodes and other such devices. Examples of passive elements include resistors and other such devices.

In certain aspects of the invention such a configuration of thin film elements where each thin film element layer are laid out so that their respective heat generating regions do not overlap with each other in the direction of thickness of the thin film element layers, a thin film device having an excellent heat dissipativity wherein each thin film element is not susceptible to the heat generated by other thin film elements can be obtained. Therefore, a thin film device that can secure a stable operation can be achieved by avoiding the influence of heat generated between thin film elements placed adjoiningly in the laminated direction.

In another aspect of the invention, the thin film element layers have non overlapping heat generating regions bonded to each other using any suitable bonding material known to those of ordinary skill. By employing a configuration of the present invention, commonly known manufacturing methods can be used to construct thin film devices. The manufacturing method of laminating each thin film element layer by applying the transfer technique disclosed in Japanese Unexamined Patent Publication No. 11-251517 can be used after individually forming each thin film element layer.

According to another aspect of the present invention, the thin film element layers have non overlapping heat generating regions laminated to glass or resin substrates with the substrate bonded to the thin film element layer using any suitable bonding material known to those of ordinary skill.

By employing a configuration of the present invention, commonly known manufacturing methods can be used to construct thin film devices. The manufacturing method of laminating each thin film element layer on a glass substrate, etc. by applying the transfer technique disclosed in Japanese Unexamined Patent Publication No. 11-251517 can be used after individually forming each thin film element layer.

The bonding material used in the present invention can be a highly heat dissipative bonding material that includes a heat dissipative silicon or a nanostructure controlling epoxy resin. Thus, it becomes possible to achieve a more stable operation of the thin film element by effectively releasing the heat generated in the heat generating region through the bonding material.

In another aspect of the present invention, when each of the thin film element layers includes two or more thin film elements, the shortest distance between the heat generating regions of the thin film elements included in different thin film element layers can be longer than the shortest distance between the heat generating regions of the thin film elements included in the same thin film element layer. Thus, even in the case where a number of thin film element layers are laminated, it becomes possible to avoid the influence of the heat generated between the thin film element layers while controlling the restrictions of the layout of elements in each thin film element layer.

In another aspect of the invention, the heat generating region in the thin film element layer can be placed in a decentralized area on one side of the thin film element layer, adjoining two of the thin film element layers can be laminated with the side (where the heat generating region is placed in a decentralized area) of one of the thin film element layers facing an opposite side of the other. Thus, it becomes possible to secure a longer distance between heat generating regions and effectively avoid the influence of the heat generated between thin film element layers.

Other aspects of the present invention include, but are not limited to, configurations where the thin film element can be a thin film transistor, thin film diode, or other substantially similar structure, or where electric circuits and other similar devices can be configured using thin film transistors, and the heat generating region is an active region of the structure.

Another aspect of the present invention is to provide an integrated circuit including the thin film device according to the above aspects of the invention. Here, the “integrated circuit” means a circuit wherein a thin film device and the associated wiring, etc. are integrated so as to provide a specific function.

Another aspect of the present invention is to provide an electrooptic device including the thin film device according to the above aspects of the invention. Here, the “electrooptic device” means a general device having the thin film device according to the above aspects of the invention, as well as an electrooptic element that emits light or changes the state of external light by using an electric reaction, including both a device that spontaneously emits light and a device that controls the permeation of external light. The electrooptic device may include, for example, an active-matrix display device, etc. that has electrooptic elements such as: liquid crystal elements; electrophoresis elements having a dispersive medium that is dispersed by electrophoresis particles; electroluminescence (EL) elements; and electron emission elements that emit light by reflecting the electrons, which are generated by applying an electric field, onto a luminous substrate.

Another aspect of the present invention is to provide an electronic device including the thin film device according to the above aspects of the invention. Here, the “electronic device” means a general device that has a semiconductor or other similar device according to the aspects of the invention and provides one or more specific functions. The electronic device can have, for example, an electrooptic device and a memory including, but not limited to, IC cards, cellular phones, video cameras, personal computers, head-mount displays, rear or front projectors, facsimiles with a display function, digital camera finders, portable TVs, PDAs, electronic organizers, electric signboards, and commercial displays.

### BRIEF DESCRIPTION OF THE DRAWINGS

The invention will be described with reference to the accompanying drawings, wherein like numbers reference like elements.

FIG. 1 is a cross-sectional view showing an illustrative configuration of a thin film device according to aspects of the present invention.

FIG. 2 is a diagram showing an illustrative layout of heat generating regions with regard to two adjoining thin film element layers in the laminated direction according to aspects of the present invention.

FIG. 3 is a cross-sectional view showing another illustrative configuration of a thin film device according to aspects of the present invention.

FIG. 4 is a cross-sectional view showing an illustrative configuration of a thin film device according to aspects of the present invention.

FIG. 5 is an illustrative diagram showing a distance secured between heat generating regions according to aspects of the present invention.

FIG. 6 is an illustrative circuit diagram of an electrooptic device including a thin film device according to aspects of the present invention.

FIG. 7 is a diagram showing illustrative electronic device including thin film devices according to aspects of the present invention.

### DETAILED DESCRIPTION OF THE INVENTION

Hereinafter, an illustrative embodiment for putting the present invention into practice is described with reference to the accompanying drawings. It is noted that various connections are set forth between elements in the following description. It is noted that these connections in general and, unless specified otherwise, may be direct or indirect and that this specification is not intended to be limiting in this respect.

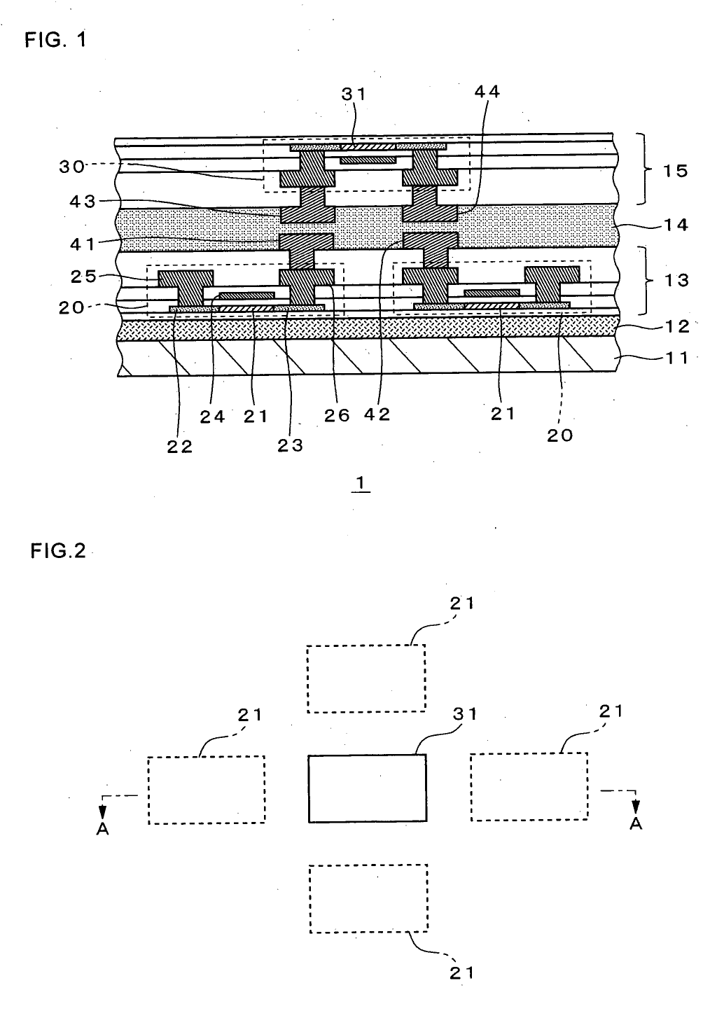

FIG. 1 is a cross-sectional view showing a configuration of a thin film device according to an illustrative embodiment of the invention. A thin film device 1 shown in FIG. 1 is configured by laminating thin film element layers 13 and 15, each of which includes one or a plurality of thin film transistors, onto an insulation substrate 11, which can be a glass substrate or an epoxy substrate. In addition, FIG. 1 shows laminating multiple thin film layers. This technique can be used to laminate three or more thin film element layers. The thin film element layers 13, and 15 are formed on the substrate 11 by employing a method well known to those of ordinary skill and disclosed in, for example, Japanese Unexamined Patent Publication No. 11-251517, which is hereby incorporated by reference in its entirety.

The thin film element layer 13 may include a plurality of thin film transistors 20 and has a specific function. The thin film element layer 13 may also contain other active elements or passive elements such as thin film diodes, resistors, and other structures that have a heat generating region that generates heat when supplied with an electric current in addition to or in substitution for one or more of the thin film transistors 20. For example the thin film element layer 13, containing a plurality of thin film transistors, or other active or passive elements in an electric circuit having a specific function is configured by appropriately providing wiring among the elements. The thin film element layer 13 is formed by employing the element transfer technique described above. Specifically, the thin film element layer 13 is transferred onto the substrate 11 from another substrate, which is to become the source of transfer (an original substrate), through the process of temporarily being formed on the original substrate and bonded with the substrate 11, with an intermediary of a bonding material 12, followed by the removal of the original substrate. Additionally, the thin film element layer 15 is transferred onto the thin film element layer 13 from another substrate, which is to become the source of transfer (original substrate), through the process of temporarily being formed on the original substrate and bonded with the thin film element layer 13 on the substrate 11, with an intermediary of a bonding material 14, followed by the removal of the original substrate. In the example, an anisotropic conductive material (or anisotropic conductive film) containing conductive particles is used as the bonding material 14. The thin film element layer 13 and the thin film element layer 15 are electrically coupled, with intermediaries of the bonding material 14 and the electrode terminals 41 to 44.

Each of the thin film transistors 20 included in the thin film element layer 13 can be configured of: a channel forming, heat generating, or active region 21 and source/drain regions 22 and 23, each of which is formed as part of an island-shaped semiconductor film; a gate electrode 24; source/drain electrodes 25 and 26; and an insulation film placed appropriately among the foregoing elements. The thin film transistor 20 of the embodiment is a field effect transistor that employs a laminated structure (MIS structure) including a semiconductor film, an insulation film, and a gate electrode. The insulation film placed among the elements can be a silicon or silicate film. Preferably, the insulation film can be a silicon oxide (SiO₂) film, a silicon nitride (Si₃N₄) film, or a phosphosilicate glass (PSG) film.

The thin film transistors 20 or other active or passive elements in the thin film layer 13 can have a configuration wherein the channel forming region is formed of a conductor or a semiconductor. A semiconductor film can be used to form the channel forming region. Preferably, an amorphous silicon film, a polycrystalline silicon film, or other similar semiconductor films can be used to form the channel forming regions. In the example, the channel forming region 21 is formed directly under the gate electrode 24 by conducting ion implantation with respect to the semiconductor film by means of a self-alignment method using the gate electrode 24 as a mask, and the highly ion-implanted regions formed on both sides of the channel forming region 21 are obtained as the source/drain regions 22 and 23.

The gate electrode 24 is formed above the channel forming region 21, which is part of the semiconductor film, with an intermediary of the insulation film (gate insulation film). The gate electrode 24 can be formed of a conductor film. Preferably, the gate electrode 24 can be formed from a tantalum, chromium, or aluminum conductor film.

Each of the source/drain electrodes 25 and 26 is coupled through the insulation film to each of the source/drain regions 22 and 23, which are part of the semiconductor film. The source/drain electrodes 25 and 26 may be formed of a conductor film. Preferably the source/drain electrodes 25 and 26 are formed of aluminum.

A bonding material 14 can be a highly heat dissipative material. Preferably, the bonding material contains a heat dissipative silicon, a nanostructure controlling epoxy resin, or other similar materials. Even more preferably, the nanostructure controlling epoxy resin is an epoxy resin that controls the crystal structure in the resin on a nanometer level, macroscopically has an anisotropic amorphous structure, with randomly positioned molecules, and microscopically has a highly ordered crystal structure with regularly positioned molecules having no interface with the amorphous structure. Such a nanostructure epoxy resin has a heat conductivity of several times as large as that of the conventional epoxy resin for general use.

Each of the thin film transistors 30 included in the thin film element layer 15 may be configured of elements including a channel forming region (active region) 31 as a heat generating region, as well as source/drain regions, a gate electrode, source/drain electrodes, and an insulation film, substantially similar to thin film transistor 20.

FIG. 2 is a diagram showing an example layout of channel forming regions with regard to two adjoined thin film element layers 13 and 15. The diagram shows an example layout of the channel forming regions when the thin film device 1 is viewed along the thickness axis of the thin film device (from the top-view direction). The channel forming region 31 in the upper layer is shown with a solid line, and the channel forming region 21 in the lower layer is shown with a dotted line. Further, FIG. 1 described above also corresponds to the cross section in the A-A direction shown in FIG. 2.

As shown in FIG. 1 and FIG. 2, in the thin film device 1 of one embodiment, the two adjoining thin film element layers 13 and 15 may be placed to give a relative shift so that the channel forming region of thin film transistors 20 included in thin film element layer 13 do not overlap with the channel forming region of the thin film transistor 30 included in the thin film element layer 15 in the direction of thickness of the thin film element layers. That is, in the adjoining thin film element layers, each of the thin film transistors is placed so that the channel forming region the thin film transistors 20 included in the thin film element layer 13 and the channel forming region of the thin film transistor 30 included in the other thin film element layer 15 are separated when the thin film element layers 13 and 15 are viewed along the thickness axis of the thin film device.

As shown in FIG. 1, one embodiment of the invention may have the channel forming region (heat generating region) of each thin film transistor placed off center in the thin film element layer. The exemplary thin film transistor 20 in the thin film element layer 13 has the channel forming region 21 placed off center and closer to the bottom surface of the thin film element layer 13. Likewise, the exemplary thin film transistor 30 in the thin film element layer 15 has the channel forming region 31 placed off center and closer to the top surface of the thin film element layer 15. Further, the two adjoining exemplary thin film element layers 13 and 15 are laminated so that the two surfaces opposite the surfaces to which the heat generating regions are closer, face each other. Thus, it becomes possible to secure a longer distance between the channel forming regions 21 and 31 and effectively avoid the influence of the heat generated between the thin film element layers.

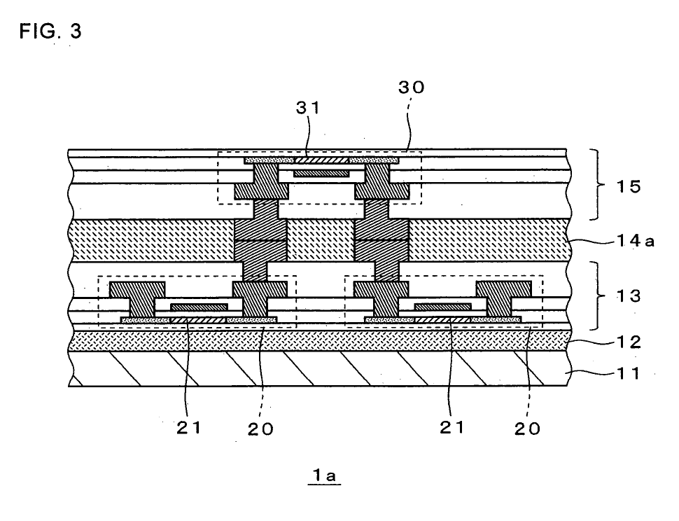

FIG. 3 is a cross-sectional view showing another embodiment of the present invention. The example differs from the thin film device 1 shown in FIG. 1 in terms of electric coupling between thin film element layers. As shown in FIG. 3, each of the electrode terminals 41 can be contacted with each other to obtain an electric coupling. In such a case, a bonding material 14a provided between the thin film element layers 13 and 15 may not be an anisotropic conductive material as described above with respect to bonding material 14. In this embodiment the bonding material 14a is preferably non conductive. Even more preferably the bonding material 14a is non-conductive material with high heat dissipation properties.

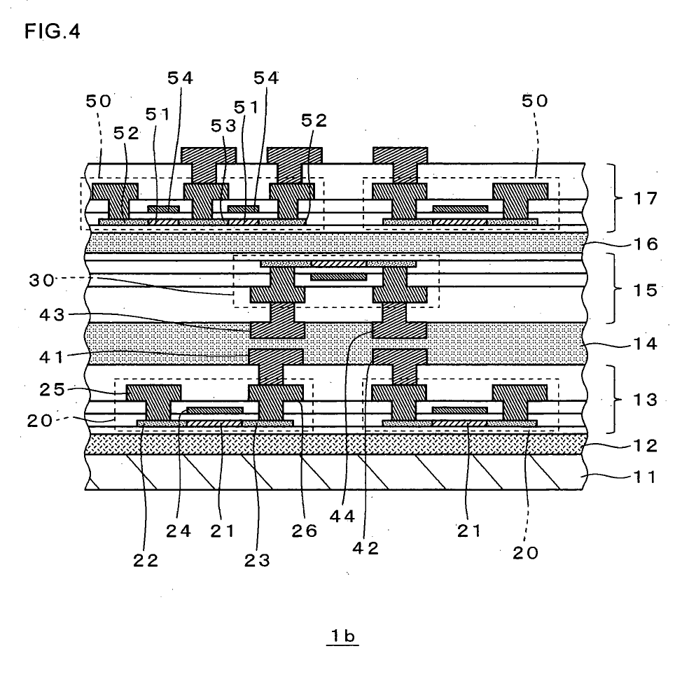

FIG. 4 is a cross-sectional view showing another embodiment of the present invention. A thin film device 1b shown in FIG. 4 has another thin film element layer 17, as the third layer, on the thin film element layer 15, in addition to the thin film device 1 shown in FIG. 1. The thin film element layer 17 includes, similar to thin film element layers 13 and 15, one or more thin film transistors 50 or other active or passive elements with an active region. Each of the thin film transistors 50 included in the thin film element layer 17 may be configured of elements including a channel forming region (active region) 51 as the “heat generating region,” as well as source/drain regions 52 and 53, a gate electrode 54, source/drain electrodes, an insulation film, etc., the same as the thin film transistor 20. The thin film element layer 17 may also be formed by employing the well known element transfer technique described above with respect to thin film element layers 13 and 15. There can be a bonding material 16 between the second thin film element layer 15 and the third thin film element layer 17. Preferably, the bonding material 16, is an anisotropic conductive material (or anisotropic conductive film) containing conductive particles. More preferably, the highly heat dissipative material 14 and 14a described above is also used as the bonding material 16. Further, the two adjoining thin film element layers 15 and 17 may be placed to give a relative shift so that the channel forming region of the thin film transistor 30 included in the one thin film element layer 15 does not overlap with the channel forming region of the thin film transistor 50 included in the other thin film element layer 17 in the direction of thickness of the thin film element layers concerned. That is, in the adjoining thin film element layers, each of the thin film transistors is placed so that the channel forming region of the thin film transistor 30 included in the one thin film element layer 15 and the channel forming region of the thin film transistor 50 included in the other thin film element layer 17 are separated when the thin film element layers 15 and 17 are viewed along the thickness axis of the thin film device.

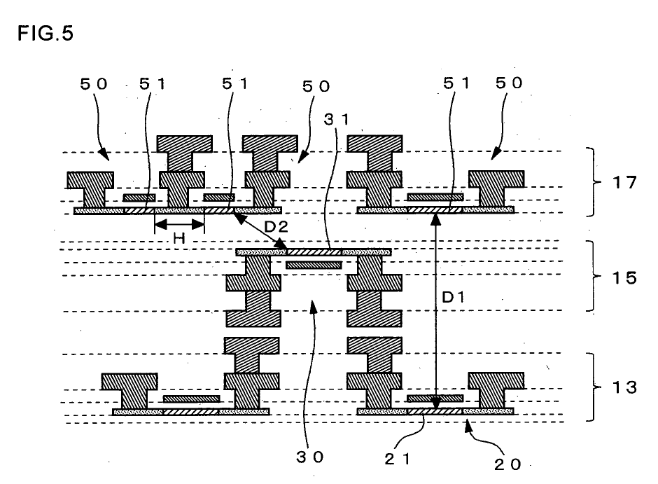

FIG. 5 is a diagram showing the distance to be secured between channel forming regions of an embodiment of the invention. FIG. 5 is a simplified diagram of thin film device 1b shown in FIG. 4. In this embodiment the shortest distance between the channel forming regions of the thin film transistors included in the same thin film element layer is H. Each thin film element layer may be formed so that the shortest distance between the channel forming regions of the thin film transistors included in two different thin film element layers becomes longer than the shortest distance H. Preferably,, the thin film device 1b of the embodiment shown in FIG. 5 is formed so that the distance D1 between the thin film transistor 20 and the thin film transistor 50 included in each of the two different thin film element layers 13 and 17 becomes longer than the shortest distance H and the distance D2 between the thin film transistor 30 and the thin film transistor 50 included in each of the two different thin film element layers 15 and 17 becomes longer than the shortest distance H. The distances D1 and D2 can be adjusted by many methods within the scope of the present invention, including but not limited to: increasing or decreasing the thickness of the source/drain electrodes, adjusting the diameter of conductive particles to be mixed into the bonding material, or separately mixing a spacer into the bonding material, or other similar methods known to those of ordinary skill.

In the embodiments of the present invention wherein the thin film transistor (thin film element) included in each of the thin film element layers 13 and 15 is laid out so that the channel forming regions (heat generating regions) do not overlap with each other in the direction of thickness of the thin film element layers, a thin film device having an excellent heat dissipative property wherein each thin film element is not susceptible to the heat generated by other thin film elements can be obtained. Therefore, a thin film device that can secure a stable operation can be achieved by avoiding the influence of the heat generated between adjoining thin film transistors in the laminated direction. Additionally, embodiments of the present invention provide thin film devices having thin film transistors with improved resistance to electromagnetic interference radiated from channel forming regions of other thin film transistors in the same device.

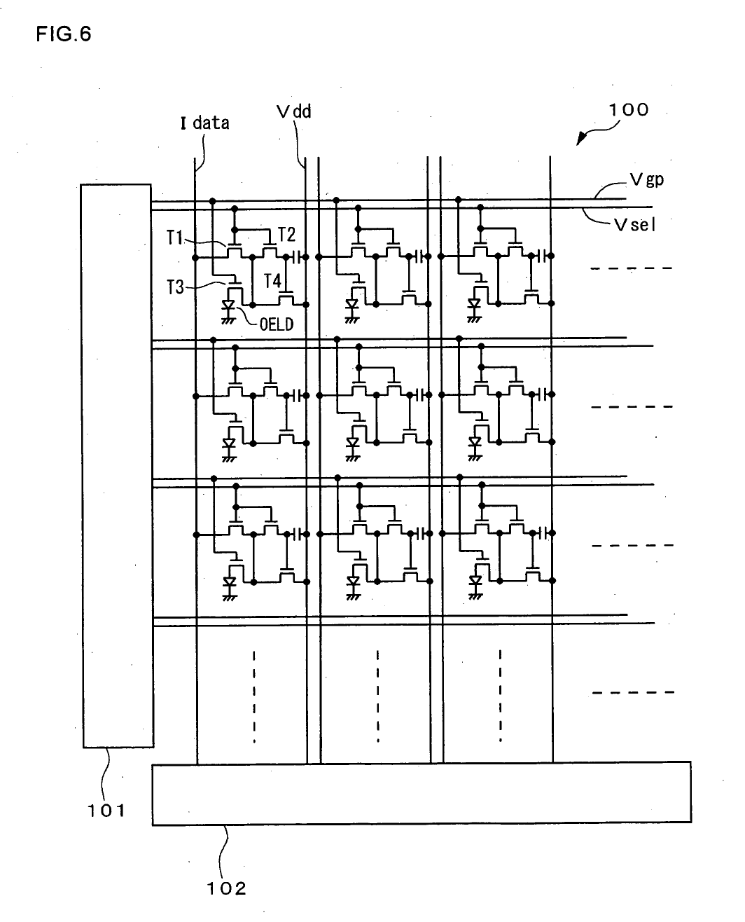

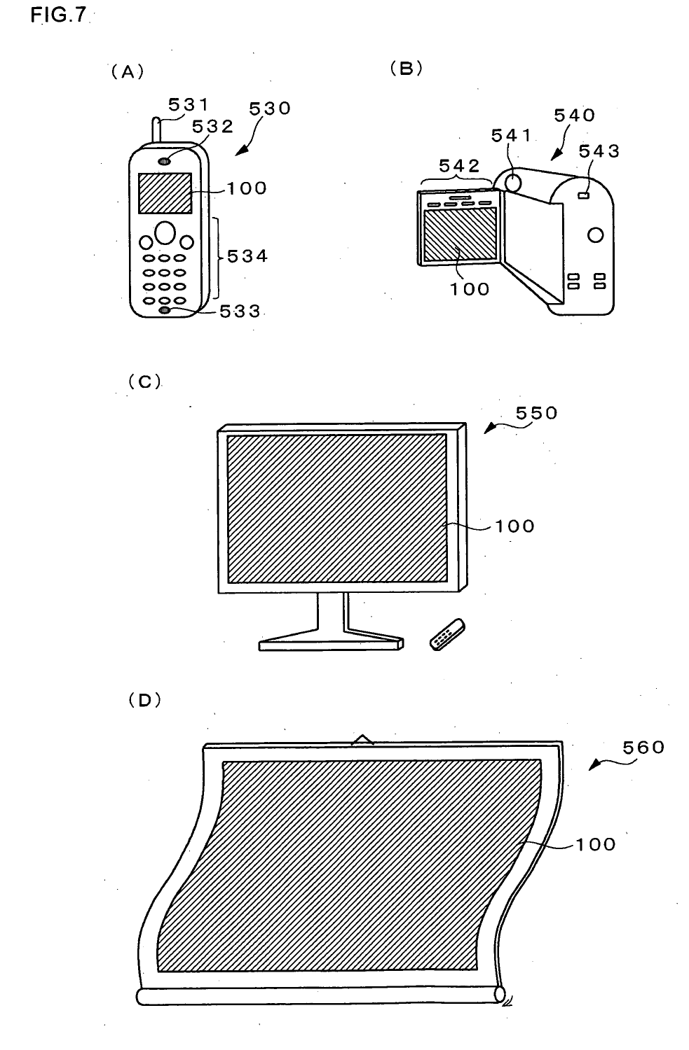

Other embodiments of the present invention include an integrated circuit, an electrooptic device, and an electronic device that include one or more of the thin film devices described above. FIG. 6 is an embodiment of the invention with an electrooptic device 100 having a semiconductor device. The electrooptic display device 100 can have in each pixel region a luminous layer OLED or other electroluminescence element known to those or ordinary skill. Preferably, the electrooptic display device 100 has in each pixel region a luminous layer OLED that emits light using an electroluminescence effect. Also included in each pixel region, a retention volume for memorizing the electric current to drive the OLED may be included as well as thin film devices with thin film transistors T1-T4 configured in a manner consistent with any of the above-described embodiments of the present invention.

From a driver 101, a scanning line Vse1 and an emission control line Vgp are provided for each pixel region. From a driver 102, a data line Idata and a power line Vdd are provided for each pixel region. By controlling the scanning line Vse1 and the data line Idata using transistors T1-T4, an electric current is programmed for each pixel region, making it possible to control the emission from the luminous unit OLED. The above drive circuit is an embodiment of the thin film device of the present invention in a circuit where an electroluminescence element is used as a luminous element. However, other well known configurations of drive circuits can be utilized using embodiments of the thin film device of the present invention. Preferably, each of the drivers 101 and 102 are configured by an integrated circuit. More preferably each of the drivers 101 and 102 also incorporates thin film devices that incorporate one or more of the embodiments of the thin film device of the present invention described above.

FIGS. 7A-D are electronic devices having one or more embodiments of the electrooptic device of the present invention. FIG. 7A shows an embodiment in a cellular phone. The cellular phone 530 has an antenna unit 531, a sound output unit 532, a sound input unit 533, an operation unit 534, and the electrooptic device 100 according to an embodiment of the present invention. FIG. 7B is an example of application of an embodiment of the electrooptic device of the present invention to a video camera. The video camera 540 has an image receiving unit. 541, an operation unit 542, a sound input unit 543, and the electrooptic device 100 according to an embodiment of the present invention. FIG. 7C is an example a television using an embodiment of the electrooptic device of the present invention. FIG. 7D is an example of application to a roll-up television. The roll-up television 560 has an electrooptic device 100 according to one or more embodiments of the present invention. Further, one or more embodiments of the electrooptic device of the present invention can be used in any electronic device with a display function, including but not limited to, personal computer monitors, facsimiles with a display function, digital camera finders, PDAs, portable TVs, electronic organizers, electric signboards, IC cards, and commercial displays. In addition, the thin film device according to the embodiment of the invention is applicable not only to the case of being included in the electronic devices listed above as a component of the electrooptic device but also to the case of being included as a sole component of electronic devices.

Further, those skilled in the art will appreciate that there are numerous variations and permutations of the above described thin film and electrooptic devices. It is to be understood that other embodiments may be utilized and structural and functional modifications may be made without departing from the scope of the present invention. Thus, the spirit and scope of the invention should be construed as broadly as set forth in the appended claims.

1. A thin film device, comprising:
a plurality of laminated thin film element layers having one or a plurality of thin film elements,
wherein: the thin film element has a heating region that generates heat with a supply of an electric current; and
each of the thin film elements is relatively placed so that the heating region of the thin film element included in one of adjoining two of the thin film element layers does not overlap with the heating region of the thin film element included in the other thin film element layer in a direction of thickness of the thin film element layers

2. An electronic device, comprising:
a plurality of device layers stacked along a first direction,
the plurality of device layers including a first device layer and a second device layer,
the first device layer having a first active element,
the second device layer having a second active element,
the first active element having a first part that generates heat,
the second active element having a second part that generates heat, and
the first part not overlapping the second part along the first direction.

3. The electronic device according to claim 2, wherein a bonding material is provided between at least two device layers.

4. The electronic device according to claim 2, wherein at least one of the plurality of device layers is disposed above a glass substrate or a resin substrate.

5. The electronic device according to claim 3, wherein the bonding material includes a heat dissipative silicon or a nanostructure controlling epoxy resin.

6. The electronic device according to claim 2, wherein
the first device layer further includes a third active element;
the second device layer further includes a fourth active element;
the third active element has a third part that generates heat;
the fourth active element has a fourth part that generates heat; and
a shortest distance between the first part and the second part is larger than a shortest distance between the first part and the third part.

7. The electronic device according claim 2 wherein the first active element and the second active element having structures reversed along the first direction.

8. The electronic device according claim 6, wherein
the first active element further has a fifth part;
the second active element further has a sixth part;
the fifth and sixth parts having an identical function in each of the first and second elements, with a geometrical relationship between the first part and the fifth part being opposite to a geometrical relationship between the second part and the sixth part with regard to an interface between the first device layer and the second device layer included in the plurality of device layers.

9. The electronic device according to claim 8, wherein the fifth part overlaps the sixth part along the first direction.

10. The electronic device according to claim 8, wherein
the first and second active elements are transistors;
the first and second parts are channel regions of the transistors; and
the fifth and sixth parts are gates of the transistors.

11. The electronic device according to claim 2, at least one active element of the first active element and the second active element being a transistor and at least one part of the first part and the second part being an active part of the transistor.

12. The electronic device according to claim 2, wherein the first and second active elements are transistors, and the first and second parts are channel regions of the transistors.

13. An integrated circuit comprising the electronic device according to claim 2.

14. An electro-optical device comprising the electronic device according to claim 2.

15. An electronic apparatus comprising the electronic device according to claim 2.

16. An electronic device, comprising:
a plurality of device layers stacked along a first direction,
the plurality of device layers including a first device layer and a second device layer,
the first device layer having a first active element,
the second device layer having a second active element,
the first active element having a first part that generates heat,
the second active element having a second part that generates heat, and
the first part separated from the second part when the plurality of device layers are viewed from the first direction.
